(19) United States
(12) Patent Application Publication
(10) Pub. No.: US 2007/0059849 A1
(43) Pub. Date: Mar. 15, 2007

(54) Method and system for BARC optimization for high numerical aperture applications

(75) Inventor: Maria Op de Beeck, Heverlee (BE)

Correspondence Address: MCDONNELL BOEHNEN HULBERT & BERGHOFF LLP, 300 S. WACKER DRIVE, 32ND FLOOR, CHICAGO, IL, 60606, US

(73) Assignee: Interuniversitair Microelktronica Centrum (IMEC), Leuven (BE)

(21) Appl. No.: 11/224,361

(22) Filed: Sep. 12, 2005

(51) Int. Cl. H01L 21/66

(52) U.S. Cl. 438/14

(57) ABSTRACT

A method is described for setting up lithographic processing of a substrate. The lithographic processing uses a bottom anti-reflective coating for minimizing the substrate reflectivity. Such bottom anti-reflective coating typically is characterized by a set of selectable BARC parameters, such as the thickness, real refractive index, and/or absorption coefficient. The method includes selecting a set of values for the BARC parameters, determining the substrate reflectivity in the resist layer using the selected BARC parameter values, thereby taking into account the angles of incidence of the incident light rays, and evaluating whether or not the selected BARC parameter values result in a sufficiently low substrate reflectivity. Preferably, together with taking into account the angles of incidence of the incident light rays, the amplitude and/or the polarization state for light rays having a different angle of incidence are also taken into account.

### FIELD

The present invention relates to lithographic processing of devices. More particularly, the present invention relates to the use of bottom anti-reflective coatings in high numerical aperture applications, such as immersion lithography.

### BACKGROUND

In the production of today's integrated circuits, optical lithography is one of the key techniques. The ongoing miniaturization of integrated circuits or other devices results in a number of problems, which may be encountered during optical lithography. When, in an optical lithographic system, light generated by a light source is incident on a mask, the light will be diffracted. The smaller the dimensions of the structures on this mask, the more the light will spread. Hence, the smaller the dimensions of the structures on the mask, the less of this spread-out light will be collected by an objective lens so as to be focused onto a resist layer. As a result, the image of the mask structure formed onto the resist layer will be of a low quality. A well-known solution to cope with the light spreading and consequently to obtain sufficient quality of the mask image is the use of systems having a high numerical aperture (NA). Typically, immersion fluids are used to deal with the corresponding incidence of light having a high angle of incidence onto the wafer.

Light, which propagated through the resist, will be reflected back into the resist by the substrate on which the resist has been deposited. The substrate itself can comprise a stack of various layers, such as a stack of dielectric layers or conductive layers formed on a semiconductor substrate. The latter typically results in multiple interference effects, depending on the transparency of the resist layer, the substrate reflectivity and the optical properties of layers underneath the resist on top of the substrate.

In lithography applications, typically bottom anti-reflective coatings (BARC) or bottom anti-reflective layers (BARL) are used underneath the resist to decrease the effects of multiple interference of light in the resist due to reflection by the substrate. In the following, the terminology bottom anti-reflective coating (BARC) will be used to refer to both BARC and BARL, which is common use in the field.

Multiple interference effects result in a variation of intensity with resist depth, causing a variation of the development rate with resist depth. As a result, the resist sidewalls have a scalloped profile, the so-called ‘standing waves’. This standing wave problem will cause pattern collapse of lines in defocus, due to strongly pronounced standing waves at the bottom of the resist line, or incomplete development of lines or contacts holes, especially in defocus. Additionally, the multiple interference effects in resist will result in a variation of total absorbed energy with resist thickness, hence in a variation of the critical dimension (CD) with resist thickness. The latter is known as the ‘swing effect’, which will cause CD non-uniformity if patterns have to be made on substrates with topography.

Using bottom anti-reflective coatings, the reduction in substrate reflectivity can take place in two ways: by absorption of light in the BARC, or by destructive interference of light rays at the bottom of the resist. The latter is illustrated in FIG. 1, showing a part 100 of a lithographic process step, wherein a device 102 is covered by a resist layer 104, and a BARC 106 is sandwiched between the device 102 and the resist layer 104. The light rays 108 show the situation whereby light is absorbed in the BARC, which is only possible if the BARC is sufficiently thick. Unfortunately, the etching of a thick BARC layer with the resist as a mask is often a problem due to excessive resist erosion.

The light rays 110 show the situation in which reflection is reduced by destructive interference, which is only possible if the BARC thickness is everywhere exactly the same, causing the required phase difference between the interfering light rays. The latter may even be obtained on topographical substrates, e.g., using inorganic BARCs. Some BARCs (e.g., organic BARCs) show planarization over topography, causing BARC thickness variations. Hence organic BARCs are typically used combining interference effects and absorption in order to reduce the substrate reflectivity on topographic substrates.

Conventionally, BARC thickness optimization, crucial for reflection control, is carried out by calculating the substrate reflectivity versus BARC thickness for light rays perpendicular incident on the wafer. Litho simulation programs or tools calculating basic optics can do this job. Typically, the substrate reflectivity will drop with BARC thickness due to absorption, but local minima and maxima are present due to interference effects, as can be seen in FIG. 2. The first minimum 122 of this curve 120 which is sufficiently low (e.g., typically below 0.5%) is considered to be the optimum BARC thickness.

Nevertheless, the above-described BARC thickness optimization method does not allow an optimum reduction of the substrate reflectivity, especially not in case of high numerical aperture lithography.

### SUMMARY

A system and method for obtaining a more efficient BARC layer in optical lithographic processing of substrates is described. A method for setting up lithographic processing of a device is described. The lithographic processing includes using at least one bottom anti-reflective layer for reducing substrate reflectivity for incident light rays. The method includes selecting values for a set of BARC parameters characterizing the at least one bottom anti-reflective layer, determining the substrate reflectivity in a resist layer for the lithographic processing using the set of BARC parameter values, and evaluating whether the determined substrate reflectivity is smaller than a maximum allowable substrate reflection. The substrate reflectivity is determined by taking into account the angles of incidence of the incident light rays. The angle of incidence is the angle of incidence with respect to the BARC layer, i.e., the angle included between the propagation direction of an incident light ray and the normal to the BARC layer.

Evaluating may include accepting the set of selected BARC parameter values if the substrate reflectivity is equal to or smaller than a maximum allowable substrate reflection and/or rejecting the set of selected BARC parameter values if the substrate reflectivity is larger than a maximum allowable substrate reflection.

After rejecting, the method may include repeating the steps of selecting, determining, and evaluating. The evaluation also may include ranking the lithographic processing determined by the set of selected BARC parameters if the substrate reflectivity is equal to or smaller than a maximum allowable substrate reflection. The ranking may be performed as a function of the determined substrate reflectivity.

Advantageously, the actual optical light path may be taken into account. Additionally, an improved substrate reflectivity may be obtained, reducing swing effects and/or obtaining an improved print.

Taking into account the angles of incidence of the incident light rays may include taking into account the angle of incidence for substantially each of the incident light rays. Substantially each of the incident light rays may be substantially each of the light rays captured by an optical diffracting element such as a lens. Alternatively, an average angle of incidence may also be used.

Taking into account the angles of incidence of the incident light rays may include taking into account at least the zero and first diffraction orders of the light beam, more preferably also higher order diffractions of the illumination beam. Taking into account the angles of incidence of the incident light rays may include taking into account all diffraction orders captured by an optical diffracting element such as a lens.

The substrate reflectivity may be determined taking into account the polarization state of the incident light rays and/or the amplitude of the incident light rays.

Evaluating may comprise evaluating the substrate reflectivity as function of a normalized image log-slope (NILS) related parameter. A further optimized substrate reflectivity may be obtained if it is taken into account that the maximum allowable substrate reflectivity is not a constant. The maximum allowable substrate reflectivity may be an increasing function of the normalized image log-slope.

A method for selecting at least one bottom anti-reflective coating for lithographic processing of a substrate is also described. The method includes selecting values for optical parameters characterizing the at least one bottom anti-reflective coating so as to obtain a substrate reflectivity smaller than a maximum allowable substrate reflection. The substrate reflectivity is determined taking into account the angles of incidence of the light rays incident on the substrate.

A method for lithographic processing of a substrate is also described. The lithographic processing includes using at least one bottom anti-reflective coating. The at least one bottom anti-reflective coating is selected by selecting values for optical parameters characterizing the at least one bottom anti-reflective coating so as to obtain a substrate reflectivity smaller than a maximum allowable substrate reflection. The substrate reflectivity is determined taking into account the angles of incidence of the light rays incident on the substrate.

A computer program product for executing any of the above described methods is also described. A machine readable data storage device storing the computer program product and the transmission of such a computer program product over a local or wide area telecommunications network is also described.

The teachings described herein permit the design of improved methods and apparatus for lithographic processing and improved methods and apparatus for setting up the lithographic processing. These as well as other aspects and advantages will become apparent to those of ordinary skill in the art by reading the following detailed description, with reference where appropriate to the accompanying drawings. Further, it is understood that this summary is merely an example and is not intended to limit the scope of the invention as claimed.

### BRIEF DESCRIPTION OF THE DRAWINGS

Presently preferred embodiments are described below in conjunction with the appended drawing figures, wherein like reference numerals refer to like elements in the various figures, and wherein:

FIG. 1 is a schematic illustration of two principles of operation of a bottom anti-reflective layer for incident light rays, absorption and destructive interference;

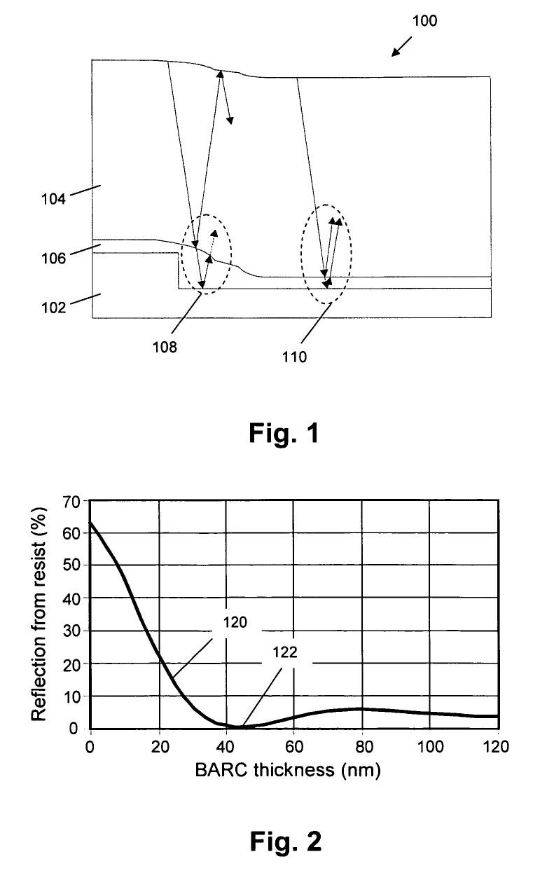

FIG. 2 is a graph of substrate reflectivity as a function of the BARC thickness, the substrate reflectivity being determined based on normal incident light;

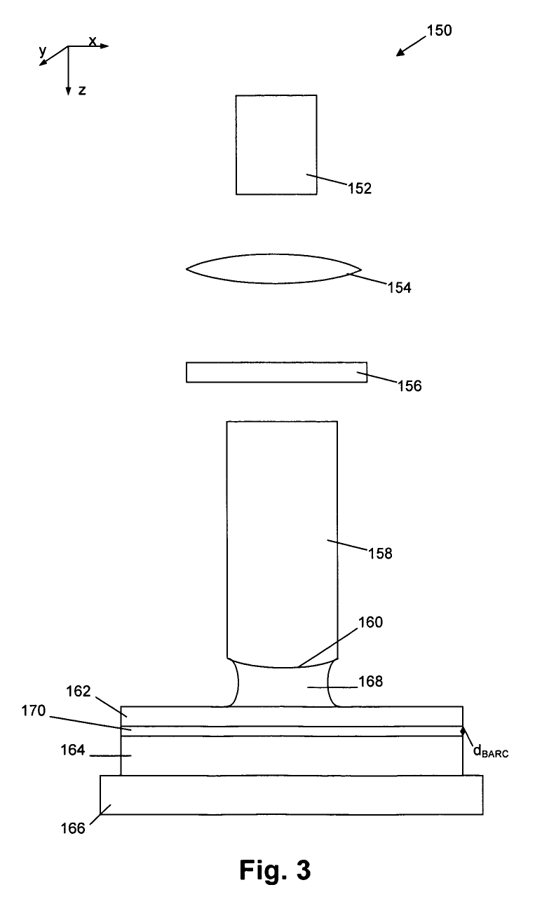

FIG. 3 is a schematic illustration of a lithographic system that can be used for lithographic processing according to an example;

FIG. 4 is a schematic illustration of different steps in a method for setting up lithographic processing according to an example;

FIG. 5a and FIG. 5b are schematic illustrations of the light path for, respectively, a standard lithographic process (FIG. 5a) and a high numerical aperture lithographic process (FIG. 5b) such as immersion lithography;

FIG. 6a to FIG. 6l are illustrations of substrate reflectivity dependency on source polarization for different pitches (FIG. 6a to FIG. 6c), for different degrees of coherence (FIG. 6d to FIG. 6f), for different dipole illumination conditions using a binary mask (FIG. 6g to FIG. 6i), and for different pitches using an alternating phase shift mask (FIG. 6j to FIG. 6l), according to an example;

FIG. 7 is a schematic representation of a processing system that may be adapted for performing any of or part of the example methods according to an example;

FIG. 8 is a graph that shows simulated substrate reflectivity as a function of BARC thickness for line structures with a 100 nm pitch for a BARC thickness determined based on reflectivity for perpendicular incident light (dashed line) and based on reflectivity taking into account the angle of incidence (full line), according to an example;

FIG. 9a and FIG. 9b illustrate simulation results and scanning electron microscope pictures of standing wave effects for a lithographic process based on a BARC thickness determined based on reflectivity for perpendicular incident light (FIG. 9a) and based on reflectivity taking into account the angle of incidence (FIG. 9b), according to an example;

FIG. 10a to FIG. 10d are graphs that illustrate critical dimension swing curves for 70 nm lines with a pitch of 140 nm (FIG. 10a and FIG. 10b) and a pitch of 420 nm (FIG. 10c and FIG. 10d), for lithographic processing using a conventional optimized BARC thickness (FIG. 10a and FIG. 10c) and using the method for optimizing the BARC thickness according to an example (FIG. 10b and FIG. 10d);

FIG. 11a and FIG. 11b are graphs that show critical dimension swing curves for 70 nm lines created using annular illumination for lithographic processing using a conventional optimized BARC thickness (FIG. 11a) and using the method for optimizing the BARC thickness according to an example (FIG. 11b), both in focus and in defocus;

FIG. 12 is a graph that illustrates the reflected light intensity in the resist as a function of the BARC thickness determined for lithographic processing of 80 nm contacts for different pitches using the angles of incidence, according to an example;

FIG. 13 is a graph that shows exposure latitude versus depth of focus for 80 nm contacts with a 160 nm pitch, in case of lithographic processing using a conventional optimized BARC thickness (dashed line) and using the method for optimizing the BARC thickness according to an example (full line);

FIG. 14a shows a graph of the substrate reflectivity as a function of the BARC thickness for normally incident light;

FIG. 14b shows the dependency of the angle of incidence for the substrate reflectivity both for a conventional optimized BARC thickness (dashed line) and for an 85 nm BARC thickness, according to an example; and

FIG. 15a to FIG. 15d are graphs that illustrate exposure latitude versus depth of focus measurements for 80 nm contacts with a 160 nm pitch (a), a 180 nm pitch (b), a 270 nm pitch (c) and a 800 nm pitch (d), for lithographic processing using conventional optimized BARC thickness and optimized BARC thickness according to an example.

### DETAILED DESCRIPTION

In the following description, substrate reflectivity means the amount of light reflected back into the resist layer, including the light reflected by any of the layers underlying the resist layer or the stack of resist layers. The latter thus also includes light reflected by a bottom anti-reflective coating.

In a first example, a method for setting up lithographic processing of a substrate is described. The method is especially suitable for setting up lithographic processing of a substrate whereby high or hyper numerical aperture (NA) lithography is used. High numerical aperture typically refers to a numerical aperture higher than 0.85, although this is not a fixed limit. Hyper numerical aperture lithography refers to lithographic processing on systems having a numerical aperture of 1 or higher.

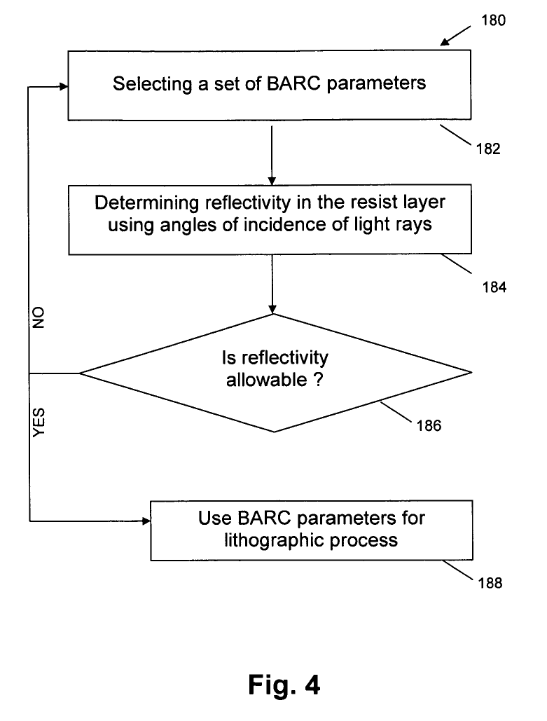

The method is applicable to lithographic processing which can be performed on any type of lithographic set-up, such as but not limited to the set-up shown in FIG. 3. This set-up is shown by way of illustration only. An optical lithographic system with a transmission set-up is shown, although the invention is not limited thereto and is also applicable to a system with a reflection set-up. It may be a lithographic stepper system or a lithographic scanner system.

The optical lithographic system 150 typically comprises a source of electromagnetic radiation, such as a light source 152. The light from the light source 152 typically is transmitted through an optical system 154 having an optical diffracting element, such as a lens or grating and is incident on a mask 156. The mask 156 contains information about the image to be generated in a resist layer and is basically defined thereby.

Typically the mask 156 may be part of a set of masks used for creating a device or circuit using lithography. Different types of masks exist, such as an alternating phase shift mask, an attenuated phase shift mask, and a binary mask. The light, carrying the mask information, is then passed through an imaging module 158, which may have a final lens surface 160, and thus is guided to a resist layer 162 on a substrate 164. The optics of the imaging module 158 inherently define the numerical aperture (NA) of the imaging module 158. It is well known by a person skilled in the art that the wider the numerical aperture, the more light (e.g., diffracted by the mask 156) that can be collected.

The substrate 164 typically is mounted on a substrate stage 166. In case of immersion lithography, typically an immersion fluid 168 is provided between the resist layer 162 and the output of the imaging module 158, e.g. the final lens surface 160, in order to allow increase of the numerical aperture of the system 150. In order to reduce substrate reflection, at least one bottom anti-reflective coating (BARC) 170 or at least one bottom anti-reflective layer (BARL), is provided between the resist layer 162 and the substrate 164. It is to be noticed that such optical lithographic systems 150 are well known by a person skilled in the art, including optional and/or additional components not illustrated in FIG. 3. It is to be noted that in the following description, bottom anti-reflective coating (BARC) will be used to refer to both BARC and BARL, as is common use in the field.

The method according to the present example is related to setting up lithographic processing of a substrate 164, whereby an advanced method for determining the optimum bottom anti-reflective coating (BARC) 170 is used such that only an allowable amount of light is reflected back into the resist layer 162. Surprisingly, it has been found that taking into account the angle of incidence for the determination of the optimum anti-reflective coating (BARC) 170, e.g. for calculation of the optimum thickness of the anti-reflective coating, may strongly influence the amount of light that is reflected back into the resist layer 162. In other words, it has been found that for determining the effective amount of light that is reflected back into the resist, referred to by substrate reflectivity, the angle of incidence of the incoming light is preferably taken into account. Based on this insight, the optimum bottom anti-reflective coating (BARC) can be determined, i.e. for example the thickness and the composition thereof can be determined.

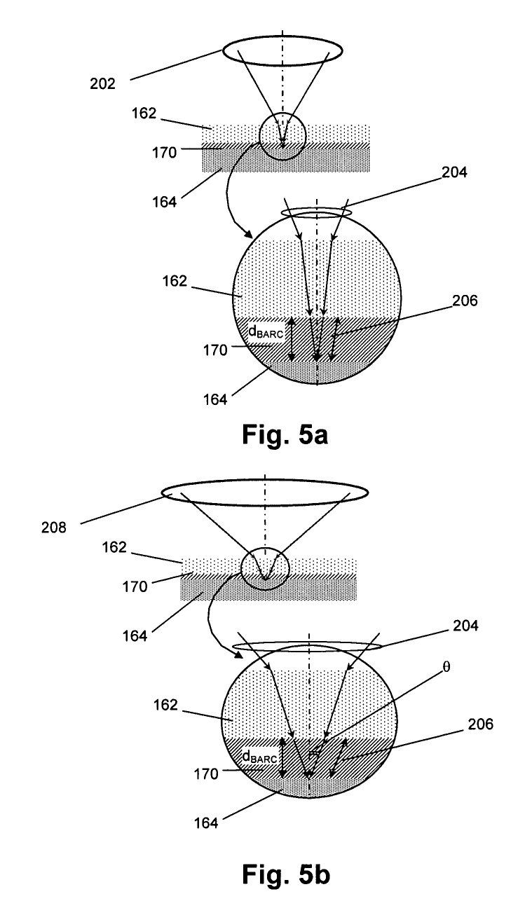

The method 180 includes selecting 182 a set of BARC parameter values, determining 184 the substrate reflectivity thereby taking into account the angle of incidence of the light rays incident on the BARC 170, the resist layer 162, and/or the substrate 164, and based on the thus determined substrate reflectivity, evaluating 186 whether the selected BARC parameter values lead to a sufficient print quality. If the selected BARC parameters values lead to a sufficient quality, optionally, these can be used, in step 188, for performing a lithographic process. By way of illustration, a more detailed description will be provided for the above-described steps of method 180, in conjunction with FIG. 4.

Selecting 182 a set of BARC parameter values may include selecting a BARC material, and thus selecting the refractive index nBARC, the extinction coefficient kBARC and a physical thickness dBARC for the BARC 170, or, if the material for the BARC 170 is predetermined, just selecting a physical thickness dBARC for the BARC 170.

Determining 184 the substrate reflectivity may be performed either experimentally or theoretically, based on a system comprising a BARC 170 having the selected BARC parameter values. The substrate reflectivity is determined by taking into account the angle of incidence of the incident light rays. The latter may be performed by taking into account an average angle of incidence of the light incident on the substrate 164, the resist layer 162 or the BARC 170, or more preferably, by taking into account substantially all angles of incidence of the different incident light rays. Hence, at least the zero order and first order diffraction but, more preferably, all diffraction orders seen by the optical imaging module 158 and the substrate 164 should be considered, taking into account their angle of incidence. Besides taking into account the angle of incidence, the present example also may relate to taking into account the polarization state of the incident light and/or the amplitude of the incident light.

The substrate reflectivity may be determined based on typical simulation programs. Substrate reflectivity refers to the amount of light reflected back in the resist layer 162 due to reflection by the substrate 164, the bottom anti-reflective coating 170, and optionally other coatings present between the substrate 164 and the resist layer 162. If the substrate reflectivity is determined by calculation or simulation, the substrate reflectivity preferably is determined by incorporating the optical parameters of all components used in the lithographic processing. Moreover, preferably all involved layers should be considered, each with its thickness and its optical constants n and k. In other words, besides taking into account the angle of incidence of the incident light ray, furthermore the amplitude of the incident light having specific angles of incidence and/or the polarization state of light rays having specific angles of incidence may be taken into account.

Evaluating 186 whether the selected BARC parameter values are sufficient or appropriate and thus allowable, can be done by evaluating whether the obtained substrate reflectivity is sufficiently low. The latter may be evaluated with respect to a fixed criterion, or more preferably, with respect to a floating criterion, i.e. depending on the normalized image log slope value. If the obtained substrate reflectivity is sufficiently low, the set of selected BARC parameter values is considered allowable and may be used for lithographic processing. If the substrate reflectivity is not sufficiently low, the set of selected BARC parameter values is not considered allowable. Such evaluation thus may be performed by simulating the substrate reflectivity. Alternatively or additionally, evaluation also may be performed by experimentally checking the obtained quality of the print, such as whether the critical dimension control for the process is sufficient.

If the set of selected BARC parameter values is not considered allowable, the method of setting up lithographic processing of a substrate 164 may also include selecting a new set of parameter values and repeating the determining and evaluation steps. Such process may be repeated until a suitable or allowable set of process parameter values is obtained. The method also may be used as an optimization method, whereby evaluating is not done with respect to a predetermined criterion (i.e., until a value better than the predetermined criterion is obtained), but with respect to obtained substrate reflectivity values for previously selected BARC parameter values (i.e., until an optimum value is obtained).

Selection of BARC parameter values may be done either systematically (i.e., in a well-defined order through a list or array of parameter values) or at random.

The method according to the present example may be performed in an automated way (e.g., based on specific computer implemented algorithms, neural networks, etc.).

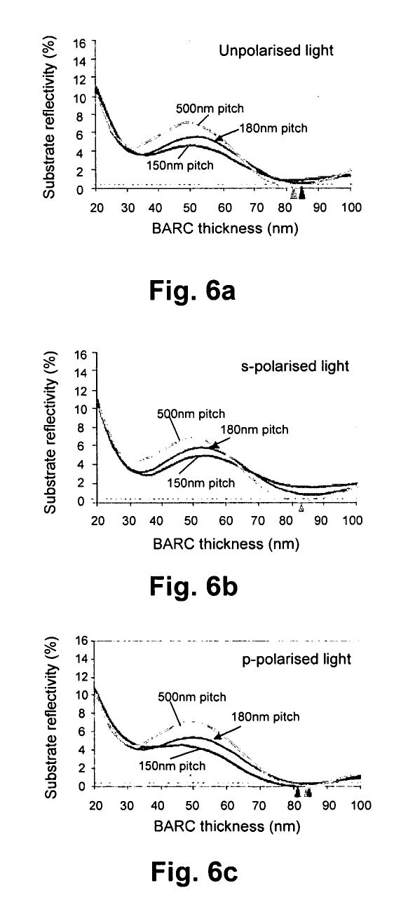

The method of the present example is especially useful in high/hyper numerical aperture (NA) applications, where at least a number of oblique light rays are present, if structures with small pitches P are patterned. The assumption that most light rays are more or less normally incident onto the substrate 164 is then not valid anymore. The latter is by way of example illustrated in FIG. 5a and FIG. 5b for the case where an alternating phase shift mask is used.

FIG. 5a illustrates the situation of an optical system with low numerical aperture 202 and light rays 204 which are substantially perpendicular to the resist layer 162, the BARC layer 170, and/or the substrate 164, resulting in an optical path length 206 of the light rays 204 being substantially equal to the physical thickness dBARC of the bottom anti-reflective layer 170. FIG. 5b illustrates the situation of an optical system with a high numerical aperture 208, and light rays 204 that are oblique, i.e., at least part of them has an angle of incidence with respect to a normal to the BARC layer 170 which is substantially larger than 0°, resulting in an optical path length 206 of the light rays 204 being substantially different from the physical thickness dBARC of the bottom anti-reflective layer 170.

In general, the optical path length of incident light rays is not substantially equal anymore to the physical thickness dBARC of the BARC layer 170 for light rays having a large angle of incidence with respect to a normal to the BARC layer 170. The optical path length is dependent on the angle of incidence θ with respect to a normal to the BARC layer 170, determining the propagation direction in the bottom anti-reflective coating 170, and thus the optical path length is dependent on the refractive index nBARC and the pitch P of the pattern as the smaller the pitch P the larger the angle of incidence will be. More in general, the optical path length 206 is dependent on the optical settings of the exposure tool, determined by the wavelength, NA, lens pupil filling factor a, also referred to as degree of coherency, and off-axis conditions, and dependent on the pitch and mask type, such as a binary mask (BIM), alternating phase shift mask (alternating PSM), or attenuated phase shift mask (attenuated PSM).

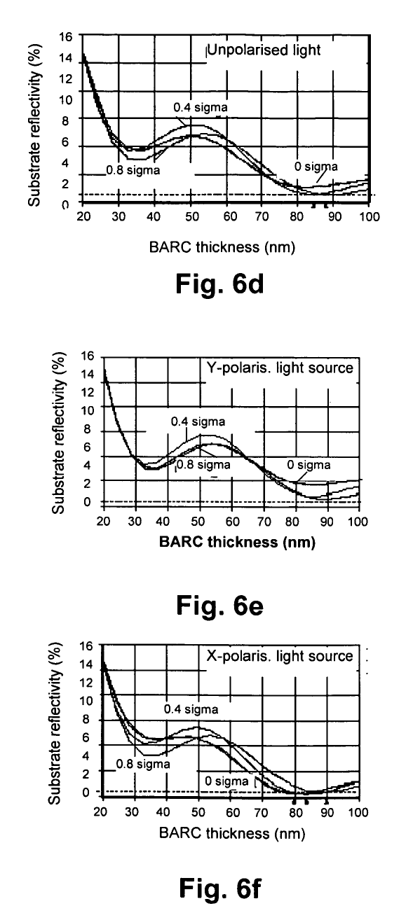

Preferably, not only the amplitude of the incident light rays is taken into account for the average angle of incidence or for substantially each angle of incidence of the incident light, but also the polarization state is taken into account. The polarization state can strongly vary with the angle of incidence, depending on a number of process parameters, such as the pitch, the duty cycle of the pattern, the degree of coherence or lens pupil filling factor, the use of off-axis light sources, the mask type, and so on. The latter will be illustrated in FIGS. 6a to 6l.

FIGS. 6a to 6l illustrate results for simulations carried out with software Solid-c (version 6.5.0.1) from Sigma-c, for 193 nm immersion litho. The optimum BARC thickness is indicated with triangles at the X-axis. The BARC layer 170 used by way of illustration is an ARC29A BARC, obtainable from Brewer Science & Nissan Chemicals. The resist layer 162 has a real refractive index n of 1.71 and an extinction coefficient k of 0.016. The system 150 is a 193 nm immersion system with a numerical aperture NA of 1.43. The duty cycle for the pattern is 1:1 Line/Spacing (L/S). For all the simulations, the situation for three types of light source polarization: for unpolarized light, for a Y-polarized light source or s-polarized light with respect to the surface of the BARC 170, and for an X-polarized light source or p-polarized light with respect to the surface of the BARC 170 is shown.

FIGS. 6a to FIG. 6c show the substrate reflectivity dependency on pitch and source polarization, for a system having a degree of coherence θ, using a binary mask corresponding with a 150 nm pitch, 180 nm pitch and 500 nm pitch. It is to be remarked that for 150 nm pitch, sufficient reflection control is only obtained for p-polarized light using the 0.5% substrate reflection criterion. It is to be noted that another optimum BARC thickness may be obtained if other BARC materials are used.

FIGS. 6d to FIG. 6f illustrate the BARC thickness optimization for a system using a binary mask with pitch 150 nm and for a degree of coherence of θ, 0.4, and 0.8. FIG. 6g to FIG. 6i illustrate the BARC thickness optimization for a system in case of different types of off-axis exposures, in this case being different types of dipole illumination of a binary mask, having a degree of coherency of σ₁=0.76, s_{σ}=0.96, or an angular illumination with angle α=35°.

FIGS. 6j to FIG. 6l illustrate the BARC thickness optimization for a system using an alternating phase shift mask with a standard illumination and for different pitches, i.e. 72 nm, 90 nm, 130 nm, 500 nm as indicated in the drawings. It can be seen that for this mask the reflection control is strongly dependent on pitch and polarization state of the light used.

It is to be noted that for the present example, a sufficiently low substrate reflectivity (e.g., lower than 0.5% or 1% depending on the NILS of the structure to be patterned) is more difficult to realize if many different angles of incidence are present and/or if most light rays are passing through the edges of the lens. If a single BARC layer is selected as solution for reflection control, the optimum thickness will be a compromise between the optimum BARC thickness for each pitch on the mask.

In a second example, the method described with respect to the first example is modified such that the evaluation of the obtained substrate reflectivity is performed using a floating criterion. Surprisingly it has been found that the maximum allowable substrate reflectivity preferably is not a constant, but depends on the normalized image log slope, or to a parameter related thereto.

The normalized image log-slope may be defined as the slope of the natural logarithm of the intensity plot, i.e. the so-called aerial image whereby the image of the photomask is projected onto the plane of the substrate assuming air is present instead of resist. In other words, in the evaluation step of the method for setting up lithographic processing of a substrate 164, evaluation of the maximum allowable substrate reflectivity preferably is performed according to a floating criterion, i.e. a non-fixed criterion. The floating criterion for the maximum allowable substrate reflectivity may be expressed as:
max.allowable amount of substrate reflectivity=f(NILS). [1]

The maximum allowable substrate reflectivity may be such that the maximum allowable substrate reflectivity is smaller for a small NILS, and larger for a large NILS. In other words, the maximum allowable substrate reflectivity may be a positive function of the NILS or a NILS-related parameter following the same trend as the NILS. Further, in a first approximation, the maximum allowable substrate reflectivity may be expressed as being proportional to the NILS, i.e.,
max.allowable amount of reflected light in resist=c.NILS [2]
with c being a constant. The constant depends on various parameters, such as resist process, resist thickness, and the required critical dimension control. The floating criterion may allow quality improvement of the lithographic print, resulting in less swing effects, a reduced collapsing of lines, a reduced incomplete development, a reduced variation in development rate of the resist, and so on.

In a third example, the method of the first and/or second examples may be used as a method for selecting at least one BARC layer as such. Selecting at least one BARC layer includes at least one of selecting a physical thickness dBARC, a real refractive index nBARC and an extinction coefficient kBARC or a parameter related thereto such that the criterion (e.g., floating criterion) for maximum allowable substrate reflectivity is fulfilled. The same features as described in any of the previous embodiments may be present resulting in the same advantages.

The results of the optimization according to any of the previous examples may be used in a method for lithographic processing of a substrate 164. The method of lithographic processing of a substrate 164 then comprises using BARC layer parameter values as obtained according to any of the methods as described above.

In a further example, a processing system for implementing the example methods is described. In other words, a processing system is adapted for performing a method 180 for setting up lithographic processing in which parameter values are selected for a BARC layer 170 used in the lithographic processing, a substrate reflectivity is determined taking into account the angles of incidence of the incident light rays, and the selected parameter values for the BARC layer 170 are evaluated based on the determined substrate reflectivity.

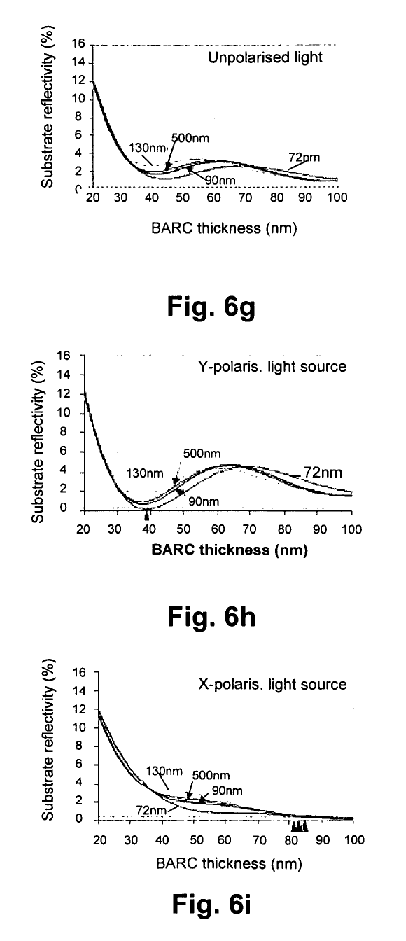

An example processing system 300 is shown in FIG. 7. FIG. 7 shows one configuration of processing system 300 that includes at least one programmable processor 303 coupled to a memory subsystem 305 that includes at least one form of memory, such as RAM, ROM, and so forth. A storage subsystem 307 may be included that has at least one disk drive and/or CD-ROM drive and/or DVD drive. In some implementations, a display system, a keyboard, and a pointing device may be included as part of a user interface subsystem 309 to provide for a user to manually input information. Ports for inputting and outputting data may also be included. More elements such as network connections, interfaces to various devices, and so forth, may be included, but are not illustrated in FIG. 7.

The various elements of the processing system 300 may be coupled in various ways, including via a bus subsystem 313 shown in FIG. 7. The bus subsystem 313 is shown for simplicity as a single bus, but is understood to those in the art to include a system of at least one bus. The memory of the memory subsystem 305 may at some time hold part or all (in either case shown as 311) of a set of instructions that, when executed on the processing system 300, implement the step(s) of the method embodiments described herein.

It is to be noted that the at least one processor 303 may be a general purpose or a special purpose processor, and may be includes in a device (e.g., a chip) that has other components that perform other functions. Thus, one or more aspects of the present invention can be implemented in digital electronic circuitry; in computer hardware, firmware, and/or software; or in various combinations. Furthermore, aspects of the invention can be implemented in a computer program product tangibly embodied in a carrier medium carrying machine-readable code for execution by a programmable processor.

Part or all of the example methods may be performed by a programmable processor executing instructions to perform functions of those aspects of the invention, e.g., by operating on input data and generating output data. Accordingly, the example system includes a computer program product which provides the functionality of any of the methods according to the present invention when executed on a computing device.

Further, the present invention includes a data carrier such as for example a CD-ROM or a diskette which stores the computer product in a machine-readable form and which executes at least one of the methods of the invention when executed on a computing device. Nowadays, such software is often offered on the Internet or a company Intranet for download, hence the present system includes transmitting the computer product over a local or wide area network.

The advantages of the methods and systems according to the present invention will be further illustrated by way of series of examples. The adjusted calculation method as described above will result in optimum BARC conditions compared to those obtained using a conventional way of calculating the substrate reflectivity. The latter is illustrated by the provided examples of several dedicated experiments.

By way of example, results for three series of experiments is provided, the first one reporting on resist profiles as function of BARC thickness, the second one on CD swing curves as function of BARC thickness, and the third one on the incomplete development of contact holes. A BARC thickness obtained using the conventional method, i.e., taking into account only perpendicular incident light will be referred to as a conventional optimized BARC thickness, whereas a BARC thickness obtained using the methods according to the embodiments of the present invention, i.e., taking into account the angle of incidence, will be referred to as advanced optimized BARC thickness.

A first series of experiments was carried out using an interference printer as exposure tool. The system is equipped with a linear polarized 193 nm laser and optics to pattern 1:1 lines with 100 nm pitch. A light source providing s-polarization is selected for the present experiment. Exposures are carried out with water as immersion fluid 168. Furthermore, a silicon substrate 164 is used, coated with ARC29A BARC 170 (n=1.82, k=0.34) underneath the resist 162 being a 100 nm thick PAR817 resist layer obtainable from Sumitomo Chemical Co. with a real refractive index n=1.723 and an extinction coefficient k=0.032.

Since the track and exposure tool are not interfaced, a topcoat is used to prevent for delay effects. The topcoat is a 130 nm thick TCX007topcoat obtainable from JSR Corporation having a real refractive index n=1.58 and an extinction coefficient k=0. In a first experiment, substrate reflection simulations are carried out, in the present example using simulation software Solid-c version 6.5.0.1 with all optical parameters as listed above, in order to define the optimum BARC thickness for reflection control.

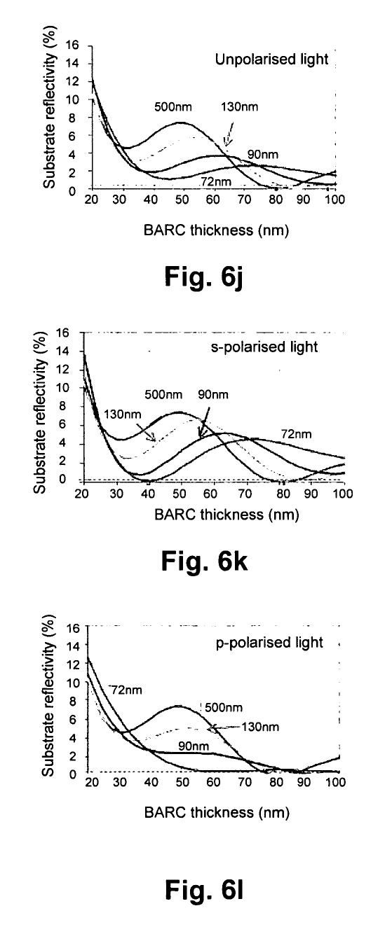

It can be seen in FIG. 8 that when only normal incidence is taken into account for calculating the substrate reflectivity, the (conventional optimized) optimum BARC thickness is around 78 nm, indicated by the dashed line. When the angle of incidence is taken into account for calculating the substrate reflectivity, the (advanced optimized) optimum BARC thickness is thicker, i.e. around 90 nm, indicated by the full line. When using the conventional optimized optimum BARC thickness, substrate reflectivity is simulated to be 1.8%, while when using the (advanced optimized) BARC thickness, substrate reflectivity is reduced to half of this value, as can be seen on the full line.

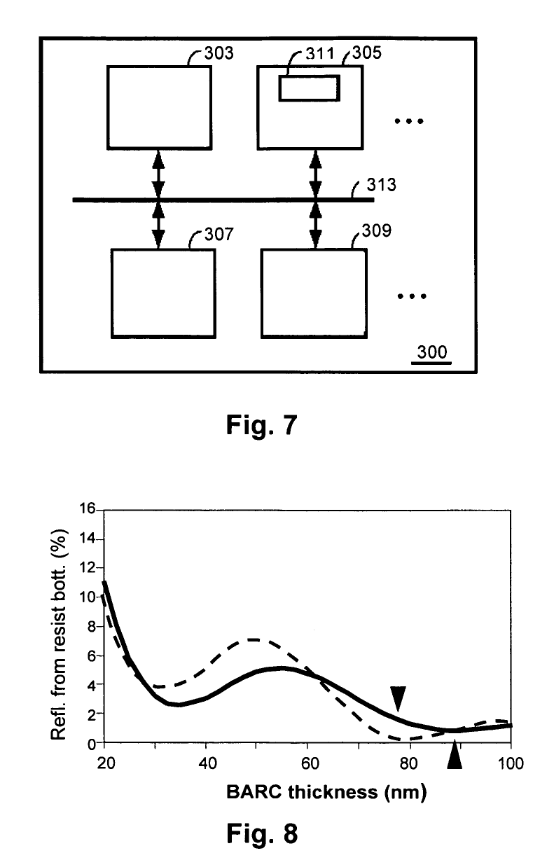

In a second experiment, substrates 164 were exposed using 78 nm BARC, corresponding with the conventional optimized optimum BARC thickness based on calculations using normal incident light, and using 85 nm BARC, close to the advanced optimized optimum BARC thickness based on substrate reflectivity calculation using the angle of incidence of the incident light. The measured cross-sections are compared with simulated resist profiles as can be seen in FIG. 9a for the conventional optimized BARC thickness, and in FIG. 9b for the advanced optimized BARC thickness. The similarity between the experiments and corresponding simulations are obvious, proving that the new calculation method for substrate reflection predicts standing wave effects well. In other words, the experiments illustrate one of the advantages obtained by optimizing the BARC thickness and correspondingly setting up the lithographic processing according to the methods and systems of the present invention.

In a second series of experiments, swing-experiments for printing lines are performed. For the swing-experiments, many exposures are carried out on the ASML XT: 1250Di immersion scanner with an NA of 0.85, and using a 6% attenuated phase shift mask (PSM). Various enhancement techniques are used to allow printing of small pitches, such as annular exposure (σ=0.93-0.69), C-quad (σ=0.96-0.76, α=20°), and dipole illumination (σ=0.93-0.69, α=40°).

During lithographic processing, illumination is performed for a substrate 164, covered by a BARC 170 and a resist layer 162. The thickness of the BARC 170 thereby is used as selectable process parameter. The substrate 164 used in the present example is a silicon wafer coated with an ARC29A BARC 170. The resist layer used was PAR817 available from Sumitomo Chemical Co.

In order to measure CD swing curves, various thicknesses for the resist layer in the range from 120 nm to 190 nm are used. In the present example, 60 nm and 70 nm lines with a duty cycle from 1:1 to isolated lines are evaluated using CD-Scanning Electron Microscopy (SEM), using the eCD SEM from KLA-Tencor, and using scatterometry, the latter in order to enhance the measurement accuracy.

First, from the obtained results, it can be concluded that for a lot of L/S structures, (almost) no swing effects are observed, for none of the BARC layers, indicating that the substrate reflectivity in the resist does not always lead to swing-problems, and no difference is seen between the old and the new BARC thickness. Second, for some pitches, an obvious swing effect is present, whereby significantly less swing occurs for the BARC thickness determined by the advanced method. It is to be noted that the importance of the substrate reflectivity in the resist layer does not typically increase for smaller pitches.

A few examples of critical dimension swing curves, being representative of the large amount of CD-swing curves measured, are presented below. In the examples, results are obtained both for an optimized BARC thickness determined in the conventional way (79 nm) whereby only normal incident light is taken into account, and for an optimized BARC thickness determined by the advanced way (87 nm) whereby the angles of incidence on the resist 162, substrate 164, and/or BARC 170 are taken into account.

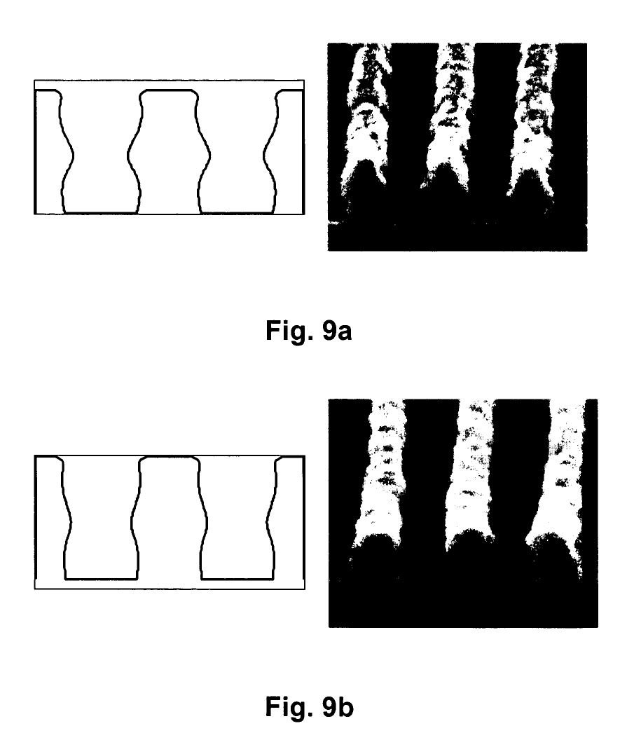

In a first example, swing curves are made for 70 nm lines with a 140 nm and a 420 nm pitch, both using dipole illumination. The 70 nm lines are measured using scatterometry. The results are plotted in FIG. 10a and FIG. 10b, indicating the results for a 140 nm pitch for the conventional optimized BARC thickness and advanced optimized BARC thickness respectively, and in FIG. 10c and FIG. 10d, indicating the results for a 420 nm pitch for the conventional optimized BARC thickness and the advanced optimized BARC thickness respectively. For a pitch of 420 nm, a clear difference is seen between both BARC thicknesses: the BARC thickness determined by the conventional method results in an obvious swing effect, whereas the BARC thickness determined by the advanced method results in superior CD control. The latter illustrates the advantages of the methods and systems according to the present invention.

For the 140 nm pitch case, almost no swing can be seen for both BARC thicknesses, indicating that in this case the sensitivity to substrate reflection is not very large. The latter is in agreement with the methods and systems of the present example, as the 70 nm lines pattern with a 420 nm pitch using dipole exposures results in a remarkably lower NILS compared to the other structures. This indicates that not only the substrate reflectivity itself plays a role, but that also the NILS or NILS related parameter plays an important role and that the maximum allowable substrate reflectivity is a function of the NILS parameter.

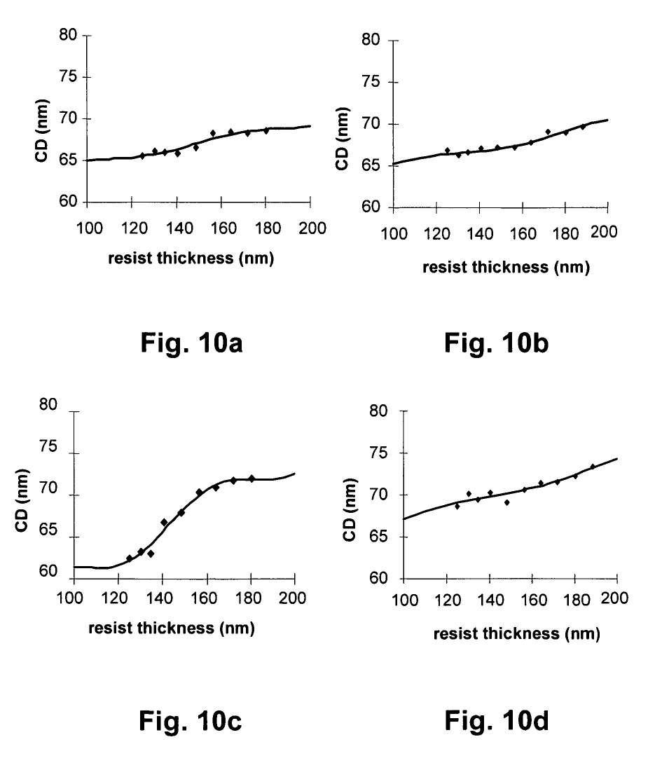

In a second example of the second series of experiments, swing curves are made for 70 nm lines using annular illumination, as shown in FIG. 11a and FIG. 11b for a conventional optimized BARC thickness and an advanced optimized BARC thickness respectively. Scatterometry is used to enhance the accuracy of the metrology, and experiments are performed in best focus and at 0.2 μm defocus. The results for the best focus are indicated by curves 602 and 606, while the results for defocus are indicated by curves 604 and 608.

As expected, the swing effects are more pronounced for the conventional optimized BARC thickness than for the advanced optimized BARC thickness. The new BARC thickness performs clearly better, although still some swing is present. Furthermore, the swing effects also are more pronounced in defocus, which is related to a decrease NILS (and hence exposure latitude) with defocus. The latter again is an illustration of the important role played by the NILS or NILS related parameter as both for 70 nm dense lines patterned with annular illumination as well as for patterns made in defocus, the NILS is remarkably lower than for other patterns or compared to the best focus case. This way, the need for a floating criterion according to the second example, i.e., away from the absolute value for maximum allowable substrate reflectivity, is supported and illustrated by the above experiment.

In a third series of examples, quality of contact development in defocus are studied. The experiments allow determination of the sensitivity of the process windows of small contacts to substrate reflectivity. The absorbed energy in the resist will suffer from standing waves if significant substrate reflections are present, resulting in a slower development of the resist. Hence contacts might not be open after the standard development time, due to the standing waves. This effect is more pronounced in defocus, hence, the focus-exposure window of contacts will be smaller in case of reflectivity problems.

For this test, 80 nm contacts are patterned with pitches from 160 nm to isolated holes. A 200 nm AJ2211 resist (e.g., available from Sumitomo Chemical Co.) is coated on top of an ARC29A BARC, and is covered with TCX007 topcoat (e.g., available from Brewer Science & Nissan Chemicals). Exposures are carried out on an ASML XT:1250i immersion scanner, using an NA of 0.85 and Quasar illumination (σ=0.93-0.57), in combination with a 6% attenuated PSM.

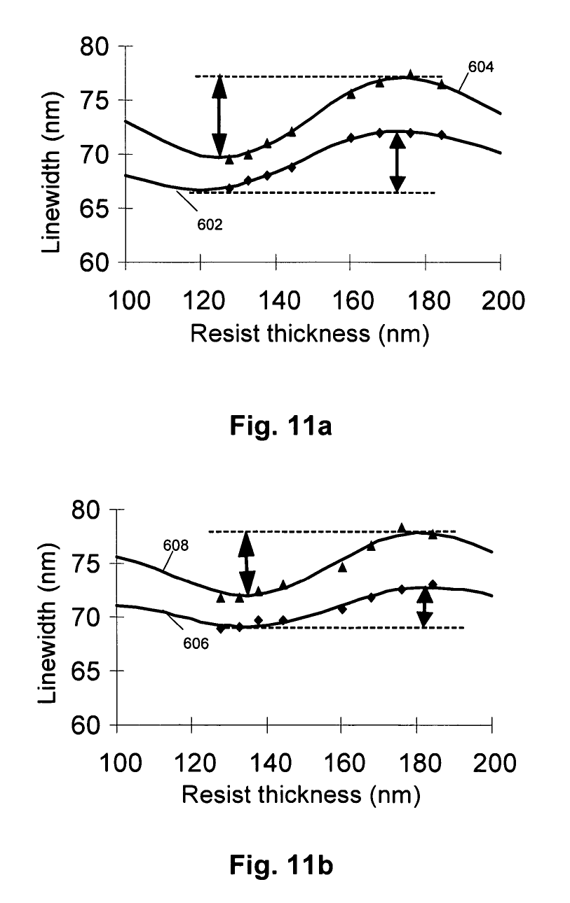

A 77 nm BARC thickness, corresponding with the conventional method of determining substrate reflectivity, and a 85 nm BARC thickness, corresponding with the advanced method of determining substrate reflectivity, are used. The latter is a compromise between the optimum thicknesses of the various pitches on the mask. This is illustrated in FIG. 12, showing the substrate reflection as function of BARC thickness for the three structures on the mask.

There is almost no difference in reflection for a 160 nm (dashed line) and 180 nm (full line) pitch, which is as expected as due to the off-axis illumination condition, the center of the lens is not used, and the difference in angles of incidence of the light rays (related to the lens pupil pattern) is rather small. A 87 μm optimum BARC thickness results. For larger pitches, the angles of incidence are smaller, and the optimum BARC thickness for a 270 nm pitch (dotted line) is 84 nm. Considering also all other pitches on the mask, a BARC thickness of 85 μm is a good compromise.

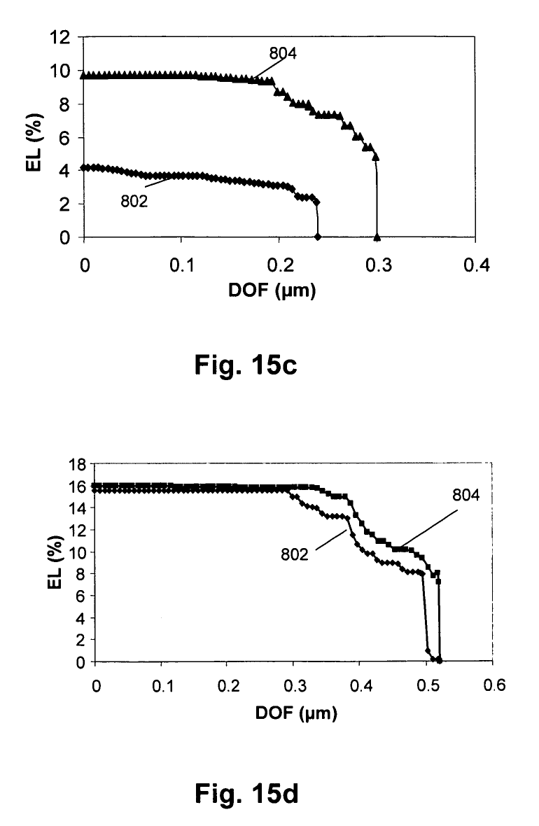

In Table 1, the obtained substrate reflection is shown for various pitches using 77 nm BARC indicated by curve 802 and 85 nm BARC indicated by curve 804, as depicted in FIGS. 15a to 15d. The reflection decreased by a factor 10 using the advanced BARC optimization method. The latter clearly illustrates one of the advantages obtained using methods and systems according to the present invention.

TABLE 1
Substrate reflection for 80 nm contacts with various pitches

| | Substrate reflection (%) | Substrate reflection (%) |
|---|---|---|
| Pitch (nm) | 77 nm BARC | 85 nm BARC |
| 160 | 0.64 | 0.056 |
| 180 | 0.64 | 0.061 |
| 270 | 0.38 | 0.032 |

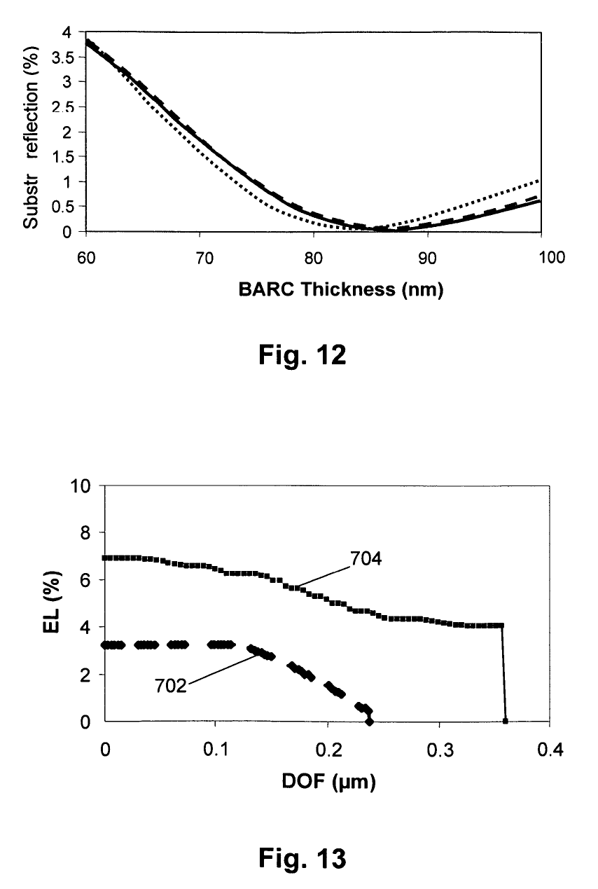

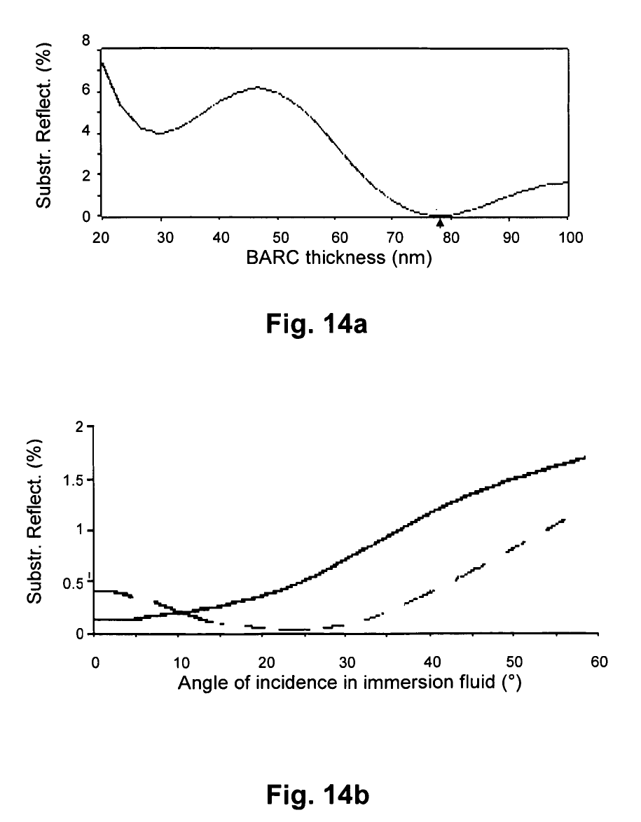

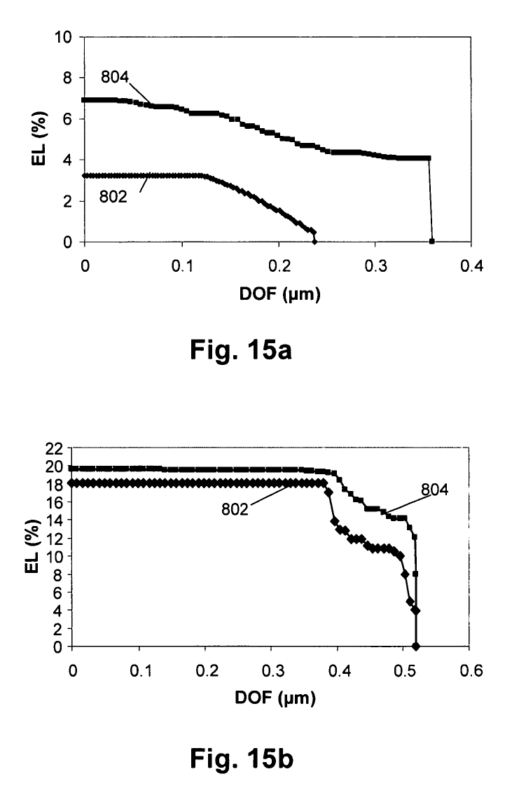

A number of results will now be discussed in more detail. For the 80 nm contacts with pitches from 160 nm to 800 nm, CD measurements are performed on a focus-exposure matrix, and the Exposure Latitude (EL) versus DOF is determined. For the 160 nm pitch, the result is plotted in FIG. 13. With the conventional optimum BARC thickness of 77 nm shown by curve 702, a clear decrease in process window is seen, due to incomplete development of contacts, while for the newly optimized thickness shown by curve 704 the process window is substantially larger, whereby the contacts are nicely open for more extreme focus and dose conditions. This difference can be easily understood by taking a detailed look at the calculations of substrate reflectivity in FIG. 14a and FIG. 14b.

The first graph shows the substrate reflectivity calculated for normally incident light, showing that 77 nm seems to be the optimum BARC thickness, since 77 nm corresponds with a reflection minimum which is well below 0.5%. From looking at the substrate reflectivity for 77 nm BARC, calculated as function of angle of incidence of light, as shown in FIG. 14b by the full line, it is obvious that the substrate reflectivity strongly increases if larger angles of incidence are considered. For comparison, the substrate reflectivity for 85 nm BARC is plotted too, shown in FIG. 14b by the dashed curve. For this BARC thickness, the reflection is higher for normally incident light, but decreases for higher angles. Since the angles of incidence for 80 nm contacts with 160 nm pitch are between 20° and 36°, 85 nm BARC will perform much better.

FIG. 15a to FIG. 15d illustrate the results for critical dimension measurements performed on a focus-exposure matrix for 80 nm contacts with a 160 nm pitch, a 180 nm pitch, a 270 nm pitch, and a 800 nm pitch respectively. The Exposure Latitude (EL) versus depth of focus (DOF) is determined, for a conventional optimized BARC thickness and an advanced optimized BARC thickness. It can be seen that for 160 nm pitch and 270 nm pitch, the BARC thickness determined by the advanced method, results in a larger process window, indicating advantages of the second embodiment. The latter illustrates one of the advantages according to embodiments of the present invention.

For 800 nm pitch, the difference between both BARC thicknesses is very small, due to the reduced angle of incidence of the light rays for the relatively large pitch, in agreement with the embodiments of the present invention. For the 180 nm pitch, although relatively large angles of incidence are involved (i.e. between 25° and 36°) the difference in process window for different BARC thicknesses and consequently for different reflectivities in the resist, is small. The NILS parameter for the 160 nm and the 270 nm pitch is significantly smaller than the NILS parameter for the 180 nm pitch. The latter indicates that the allowable substrate reflectivity is not a fixed limit, but that it depends on the NILS value. In other words, the conventional criterion of 0.5% for maximum substrate reflection is clearly not valid anymore, in agreement with the second example.

The above examples illustrate the importance of realizing that the amount of substrate reflectivity depends on the angle of incidence, as described by the methods and systems of the present invention.

It should be understood that the illustrated embodiments are examples only and should not be taken as limiting the scope of the present invention. The claims should not be read as limited to the described order or elements unless stated to that effect. Therefore, all embodiments that come within the scope and spirit of the following claims and equivalents thereto are claimed as the invention.

I claim:

1. A method for setting up lithographic processing of a device, the lithographic processing comprising using at least one bottom anti-reflective layer for reducing substrate reflectivity for incident light rays, the method comprising:
selecting values for a set of bottom anti-reflective coating (BARC) parameters characterizing the at least one bottom anti-reflective layer;
determining the substrate reflectivity in a resist layer for the lithographic processing using the set of BARC parameter values; and
evaluating whether the determined substrate reflectivity is smaller than a maximum allowable substrate reflection, wherein the substrate reflectivity is determined by taking into account angles of incidence of the incident light rays.

2. The method of claim 1, wherein the taking into account the angles of incidence of the incident light rays comprises taking into account the angle of incidence for substantially each of the incident light rays.

3. The method of claim 1, wherein the substrate reflectivity is determined by taking into account a polarization state of the incident light rays.

4. The method of claim 1, wherein the substrate reflectivity is determined by taking into account an amplitude of the incident light rays.

5. The method of claim 1, wherein the substrate reflectivity is determined by taking into account both a polarization state of the incident light rays and an amplitude of the incident light rays.

6. The method of claim 1, wherein the evaluating comprises evaluating the substrate reflectivity as function of a normalized image log-slope related parameter.

7. A method for selecting at least one bottom anti-reflective coating for lithographic processing of a substrate, the method comprising:
selecting values for optical parameters characterizing the at least one bottom anti-reflective coating so as to obtain a substrate reflectivity smaller than a maximum allowable substrate reflection, wherein the substrate reflectivity is determined taking into account angles of incidence of the light rays incident on the substrate.

8. The method of claim 7, wherein the substrate reflectivity is determined by taking into account a polarization state of the light rays incident on the substrate and an amplitude of the light rays incident on the substrate.

9. A method for lithographic processing of a substrate, the lithographic processing comprising:
using at least one bottom anti-reflective coating, the at least one bottom anti-reflective coating being selected so as to obtain a substrate reflectivity smaller than a maximum allowable substrate reflection, wherein the substrate reflectivity is determined taking into account angles of incidence of the light rays incident on the substrate.

10. A computer program product for executing a method for setting up lithographic processing of a device, the lithographic processing comprising using at least one bottom anti-reflective layer for reducing substrate reflectivity for incident light rays, comprising:
a processor;
data storage;
program instructions stored in the data storage and executable by the processor to perform functions including:
selecting values for a set of BARC parameters characterizing the at least one bottom anti-reflective layer;
determining the substrate reflectivity in a resist layer for the lithographic processing using the set of BARC parameter values; and
evaluating whether the determined substrate reflectivity is smaller than a maximum allowable substrate reflection, wherein the substrate reflectivity is determined taking into account the angles of incidence of the incident light rays.

11. The computer program product of claim 10, wherein the computer program product is transmitted over a local or wide area telecommunications network.
